(19) United States
(12) Patent Application Publication
(10) Pub. No.: US 2006/0133054 A1
(43) Pub. Date: Jun. 22, 2006

(54) Top or bottom part for a module chassis

(76) Inventors: Volker Haag, Bad Wildbad (DE); Michael Joist, Gaggenau (DE); Andreas Lenkisch, Pforzheim (DE); Hans-Jorg Weiler, Ettlingen (DE)

Correspondence Address: SCHWEGMAN, LUNDBERG, WOESSNER & KLUTH, P.A., P.O. BOX 2938, MINNEAPOLIS, MN, 55402, US

(21) Appl. No.: 10/757,966

(22) Filed: Jan. 15, 2004

(30) Foreign Application Priority Data
Jan. 17, 2003 (EP) 03 001 015.1

(51) Int. Cl. H05K 7/18; H05K 7/14

(52) U.S. Cl. 361/756; 361/802

(57) ABSTRACT

A top or bottom part made of sheet metal for a module chassis has a surrounding frame and guide rails that are positioned between the front and rear frame strip and aligned in the direction of insertion for the mounting of the circuit board of a plug-in module. The guide rails are U-shaped in cross section and include a bottom and two sidewalls. The sidewalls of the guide rails have at least one lateral void. The voids can be located on both sidewalls of the guide rail and can be opposite each other in pairs. The voids of the sidewalls correspond with at least one contact area at the lower edge of the circuit board.

### RELATED APPLICATION

This application claims priority under 35 U.S.C. 119 from European Application No. EP 03 001 015.1 filed Jan. 17, 2003, which application is incorporated herein by reference.

### FIELD OF THE INVENTION

The invention concerns a top or bottom part for a module chassis, with a surrounding frame and with guide rails that are positioned between the front and rear frame strip and aligned in the direction of insertion for the mounting of the circuit board of a plug-in module.

### BACKGROUND OF THE INVENTION

Electronic and electrical devices in the electronic industry are built in the form of modular module chassis. The module chassis are used for the mounting of insertable electronic plug-in modules, which are inserted in the intended plug-in slots. In its most simple form the module chassis includes two sidewalls and four parallel module bars which border with their front sides on the two side walls. A cover plate and bottom plate as well as a back wall can complement the module chassis to a case. From the open front side the plug-in modules are inserted on guide rails, which are most often individually mounted on the front and rear module bars.

Guide rails mounted on the module bars are usually made from synthetic material and mounted to the module bars in such a way that the partial-front plates of the inserted plug-in modules border on each other. Plug in modules with partial-front plates with a different width can be combined by a variable arrangement of the guide rails. A subsequent relocation of the guide rails is also possible with little effort. U.S. Pat. No. 4,323,161, for example describes such guide rails for the mounting of plug-in modules. Several guide rails are mounted at a distance from each other in a frame-like module chassis. The guide rails itself are flattened in the center and curved, so that a saddle-like deformation is created. The deformation is always positioned in the center of the guide rail. With that, it is intended that the lateral stiffness of the individual guide rails improves.

In many electronic systems a variable arrangement of the individual guide rails is not necessary so that a relatively expensive design of a module chassis of the common kind, consisting of a lot of individual parts, can be forgone. Especially the manual, subsequent mounting of the guide rails considerably increases the manufacturing cost of such module chassis. It is because of those costs that to an increasing extent the bottom and top groups of the module chassis are not manufactured from a multitude of individual parts anymore. Instead, the complete bottom part or the top part of the module chassis are formed from one component, which includes the module bars, the bottom and top cover and the guide rails.

Such an integrated bottom or top part includes, in principal, a rectangular sheet metal, whose edges are beveled once or several times. The beveling serves the stiffening; and they also offers an attachment area for the side parts of the module chassis and are mounting points for the adjacent parts. The guide rails are worked out of the sheet metal. For that slots are worked into the metal in such a way that a surrounding frame and ties that run parallel between the front and rear frame strip are created. The width of each tie corresponds with the width of the bottom of a guide rail plus the height of the two sidewalls of the guide rail. The side walls of the guide rail are bent from the ties by 90 degree, so that a U-shaped guide rail is created. Two adjacent guide rails are arranged in a distance of at least twice the height of the guide rail. At a larger distance between two adjacent guide rails the remaining areas can be removed, if for example an improved ventilation of the module chassis is asked for. This can be necessary especially during the use of modern plug-in modules with high clock frequencies or high power input.

Module bars as integrated parts of the top or bottom sheet metal are, for example, described in DE 198 17 089 C1. In U.S. Pat. No. 6,185,109 B1 a module chassis is revealed whose upper and lower cover plate is illustrated as a one-piece metallic guiding grid. The guiding grid shows several guiding rails for the mounting of electronic plug-in modules and has openings located between the guide rails.

Modern plug-in modules in electrical and electronic systems contain high-integrated semiconductor components and are therefore especially exposed to electrostatic discharge. Due to the low control level in the electronic circuit with at the same time very high clock frequencies and corresponding short entry times of the logic component even relatively small charges can lead to disturbances on the circuit board or even the destruction of individual components. Especially under unfavorable climatic conditions high charges can accumulate very fast on the plug-in modules. During the insertion of the plug-in modules into the module chassis, but at the latest when the plug-in module comes into contact with the backplane mother board of the module chassis, the potentials between the charged plug-in module and the component bar that lays on the ground potential balance out abruptly. Because of that, extremely high discharge currents can appear for a short period of time, which leads to damages or destruction.

To avoid an uncontrolled discharge of the plug-in module during the insertion into the module chassis a strip-like metallic area is usually intended at the lower edge of the circuit board. This contact strip at the lower edge is divided in several sections, so called segments. These segments are galvanic connected with different areas of the circuit board.

For example, a segment is connected with the logic part of the plug-in module, another one with the ground areas. Normally the front plate of the plug-in module as well is galvanic bonded with a specific segment at the lower edge of the circuit board.

Customarily a contact element is integrated in the guide rails of the module chassis. That contact element is usually formed as contact spring and is located at the front end of the guide rail. The contact element is conductively connected with the module chassis.

The individual segments are now grinding by the contact elements of the guide rail in the lower edge of the circuit boards during the insertion of the plug-in module into the module chassis, so that the areas that are connected with the segments are discharged one after the other and independently from each other in a controlled way on the circuit board. For that, resistors can be arranged in the discharge path on the circuit board that has the purpose to limit the discharge current to a permissible and for the plug-in module agreeable level.

Module chassis in which the complete bottom or top part are built out of on piece of sheet metal the guide rails are also made of metal, just like the side walls of the module chassis. Problems will arise if a plug-in module is inserted in these continuous metallic guide rails: the individual segments at the lower edge of the circuit board will be connected with each other by the metallically conductive side walls of the guide rails and therefore cause a short-circuit. With that the individual logic parts and ground areas are also galvanic connected with each other on the circuit board. In unfavorable cases this can lead not only to disturbances but can certainly lead to the destruction of a plug-in module or individual electronic components.

To avoid such short circuits the sidewalls of the guide rails are removed in those areas that correspond with the conductive segments at the edge of the circuit board. By that it is avoided that the logic part and the voltage-carrying parts of the circuit board are grounded with the chassis ground.

Sometimes the void in the sidewalls of the guide rails must be quite big. It is hereby a disadvantage that the voids of the sidewalls drastically reduce the stiffness of the guide rails. Negligently inserted plug-in modules cause bending or lead to damages on the individual guide rails. In some cases the guide rails could even break.

It is a further disadvantage that the plug-in modules could easily be caught on the voids of the sidewalls of the guide rails during the insertion into the module chassis and a smooth insertion of the plug-in modules into the module chassis is not guaranteed any more. On the contrary, the plug-in module must be inserted very carefully into the guide rail by back and forth movements. The hooking on the cutting edges of the breaks of the sidewalls can also cause damages on the circuit board or the plug-in module itself.

### SUMMARY OF THE INVENTION

One embodiment includes a top part or a bottom part for a module chassis with integrated guide rails that can inexpensively be created from sheet metal and has a sufficient mechanical stability and at the same time safely avoids that certain areas of the lower edge of the circuit board get in contact with the guide rail when the circuit board is completely inserted.

One embodiment includes a top part or a bottom part made of sheet metal for a module chassis with a surrounding frame and with two guide rails that are arranged between the front and rear frame bar in the direction of insertion for the mounting of a circuit board of a plug-in module, whereby the guide rails are u-shaped in cross section and have a bottom and two sidewalls.

The sidewalls of the guide rails have at least one lateral void. This void guarantees that the guide rail has areas that do not come in contact with the lower edge of the circuit board of the plug-in module. At the same time the sidewalls of the guide rails are not interrupted, so that the stiffness and stability of the guide rail remain fully intact.

The voids of the sidewalls correspond with the contact strips (segments) at the lower edge of the circuit board of the plug-in module. It is therefore guaranteed that the contact strips, the current-carrying areas at the lower edge of the circuit plate respectively, do not have contact with the guide rails if the component is completely inserted. This way it will be avoided that current-carrying, conductive parts of the circuit board respectively, are unintentionally connected via the guide rails with the case of the module chassis or even with each other. The voids of the sidewalls replace the known voids in the sidewalls of the common guide rails. But contrary to those, the guide rails, according to the invention, are not weakened by the voids in the sidewalls and their stiffness is not reduced.

In one embodiment, the voids are located on both sidewalls of the guide rails. That way technical characteristics of the individual circuit boards can be addressed. Especially advantageous is this variation for the use of plug-in modules with double-layer or multi-layer circuit boards.

In particular, the voids of both sidewalls can be arranged in pairs opposite each other. Then, the guide rails have a symmetric design.

Especially advantageous is a top or bottom part, in which the distance between the two sidewalls of a guide rail corresponds with the thickness of the circuit board of the plug-in module and the voids in the sidewalls of the guide rail are directed to the outside. The circuit board is then held by the sidewalls of the guide rail. The voids represent the segmented areas in which the circuit board has no contact with the guide rail. During the creation of such a variation the guide rails are formed first, whereby the distance between the sidewalls corresponds with the thickness of the circuit board. Subsequently, the voids are partially bent from the sidewalls to the outside.

Advantageous is a variation in which the area of the void of the sidewalls is separated from the bottom of the guide rail. This generates a slit-like opening in the area of the voids on the bottom of the guide rail.

That way it is avoided that during the deformation of the sidewalls the bottom of the guide rail is deformed as well. With sidewalls that are free-cut this way in the area of the voids the bottom of the guide rail remains flat, even after the deformation of the sidewalls. The plug-in modules can smoothly be inserted into the guide rail.

Slanted or rounded junctions between the sidewalls and the voids of the guide rails have the advantage that cracks and sharp edges are avoided. That way the circuit board, plug-in module respectively, does not get caught during the insertion into the module chassis. Damages to the circuit board because it is caught or scratching along sharp edged junctions during the insertion are therefore eliminated.

### BRIEF DESCRIPTION OF THE DRAWINGS

An example of a variation of the invention will be further explained with the help of the enclosed illustrations. They show:

FIG. 1 a perspective view of a module chassis with top part and bottom part, in accordance with one embodiment;

FIG. 2 the bottom part of the module chassis of FIG. 1;

FIG. 3 a perspective illustration of a guide rail with voids, as part of the bottom part from FIG. 2;

FIG. 4 a top view of the guide rail according to FIG. 3;

FIG. 5 a perspective view of a guide rail with free-cut voids, in accordance with one embodiment; and

FIG. 6 a part of the guide rail of FIG. 5, in top view.

### DETAILED DESCRIPTION

The following detailed description and accompanying drawings show specific embodiments in which the present invention may be practiced. These embodiments are described in sufficient detail to enable those skilled in the art to practice the invention. Other embodiments may be utilized and structural changes may be made without departing from the scope of the present invention.

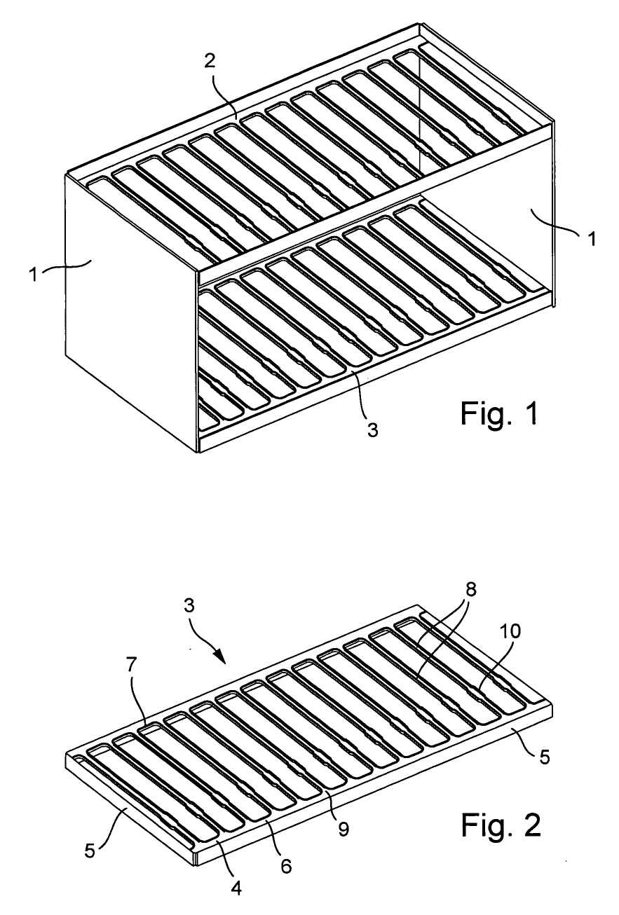

The module chassis in FIG. 1 includes two side parts 1, a top part 2 and a bottom part 3. The top part 2 and bottom part 3 can be made of sheet metal. The top part 2 and the bottom part 3 are arranged between the two side parts 1, whereby the top part 2 is fastened in the upper area of the side part 1 and the bottom part 3 in the lower area of the side part 1.

FIG. 2 shows the bottom part 3 in detail. The bottom part 3 has a surrounding frame 4 whose outer areas are slanted down, which creates edge areas 5 that are aligned vertically to the bottom part 3. The edge areas 5 represent mounting areas for the side parts 1 and, if necessary, for a back wall or front plate.

Guide rails 8 are worked out between the front and rear frame strips 6, 7 of the frame 4. The guide rails 8 run in direction of insertion and form, together with the surrounding frame 4, a grid like structure.

The guide bars 8 have a funnel-like opening 9 at the front end. Plug-in modules that are inserted into the guide bar 8 are guided through the opening 9 into the guide bars 8. Additional springy contact elements (not illustrated) could also be arranged in the area of this funnel-like opening 9 which are connected through a resistor with the case of the module chassis. That forces a controlled discharge of the plug-in modules in the lower area of the circuit board during the insertion of plug-in modules with discharge areas.

Each of the guide rails 8 has at its front area two voids 10 that are opposite from each other in pairs and directed to the outside.

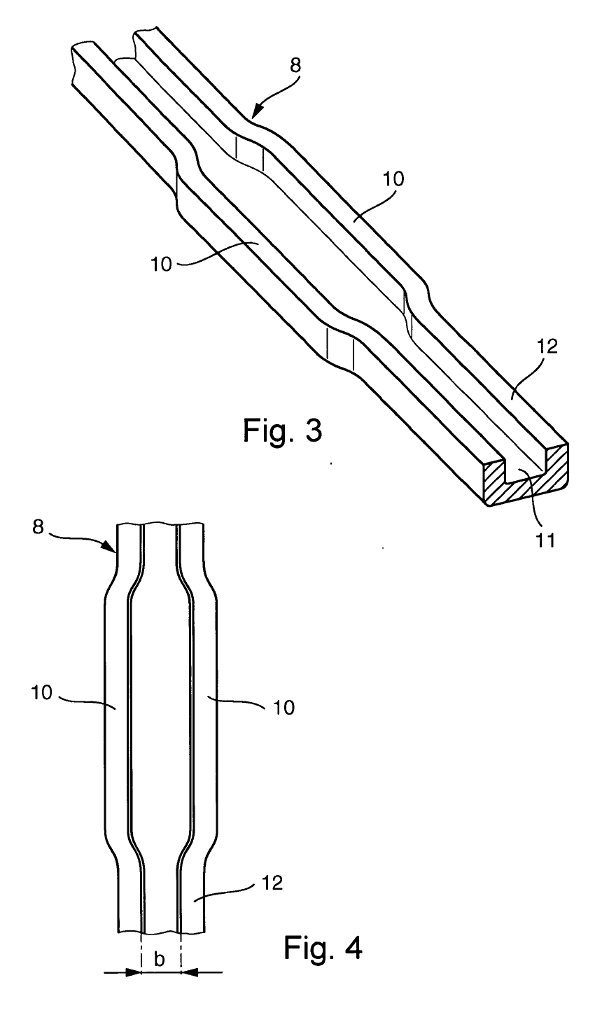

FIG. 3 shows the voids 10 of the guide rail 8 in detail. The guide rail 8 is designed u-shaped. It includes a bottom 11 and two sidewalls 12. The voids 10 are formed towards the outside. The junction from the normal running sidewall 12 to the void 10 is realized with large radiuses. In the center area of the void 10 the void 10 runs just as parallel as the sidewalls 12.

FIG. 4 shows the symmetric arrangement of the opposite paired voids 10 of the guide rail 8. The junction between the sidewall 12 and the void 10 runs continuous. The junction is designed with large radiuses to avoid sharp edges.

The distance b between two sidewalls 12 corresponds with the thickness of the circuit board of a plug-in module. A plug-in module is therefore guided between the sidewalls 12. On the other hand the circuit board has no contact with the guide rail 8 in the area of the void 10.

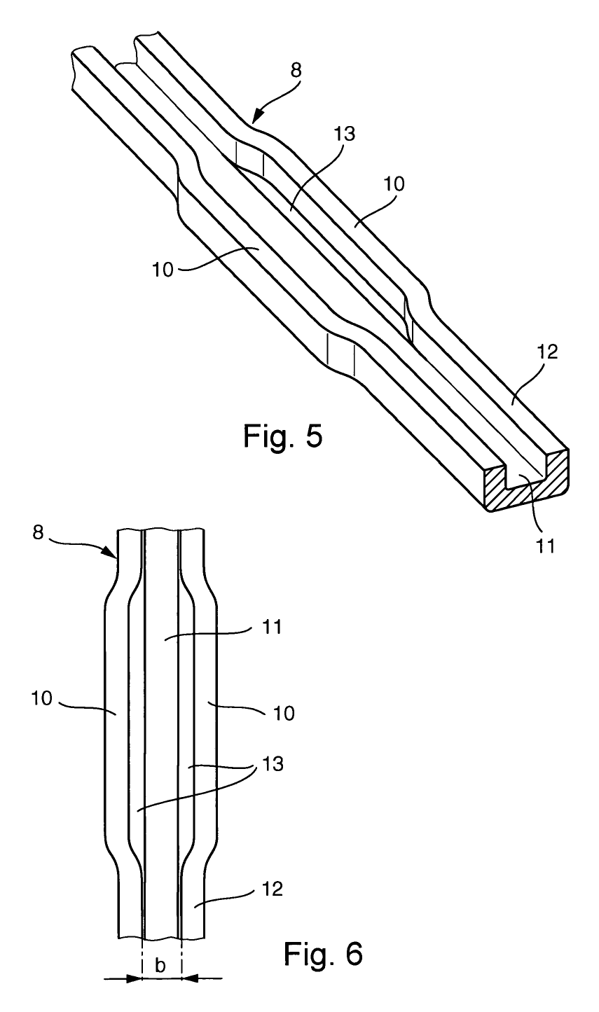

FIG. 5 shows one embodiment of a guide rail 8. The sidewall 12 is cut free from the bottom 11 of the guide rail 8 in the area of the voids 10. This separation between bottom 11 and the void 10 causes a slit-like opening 13. The separation of the void 10 from the bottom 11 especially avoids that because of the deformation of the sidewalls 12 in the area of void 10 the bottom 11 will also be deformed.

The free-cut voids 10 are shown in FIG. 6 in top view. The openings 13 between bottom 11 and the voids 11 can clearly be seen.

The above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

What is claimed is:

1. A top or bottom part for a module chassis, comprising:
a frame having front and rear frame strips; and
guide rails that are positioned between the front frame strip and the rear frame strip and aligned in the direction of insertion for the mounting of a circuit board of a plug-in module, wherein the guide rails, in cross section, are formed in a u-shape and include a bottom and two sidewalls, at least one of the sidewalls having at least one lateral void, the void of the at least one sidewall corresponding with at least one contact area at a lower edge of the circuit board.

2. The top or bottom part of claim 1, wherein both sidewalls of the guide rail each have at least one void.

3. The top or bottom part of claim 2, wherein the voids are positioned in pairs opposite each other.

4. The top or bottom part of claim 1, wherein a distance between the sidewalls of the guide rail corresponds with a thickness of the circuit board.

5. The top or bottom part of claim 1, wherein the sidewalls are separated from the bottom of the guide rail in the area of the at least one void so that a slit-like opening is created.

6. The top or bottom part of claim 1, wherein a junction between the at least one sidewall and the at least one void is slanted or rounded.

7. A top or bottom part for a module chassis, comprising:
a frame; and
one or more guide rails attached to the frame and adapted to hold a circuit board, each guide rail having a bottom and a pair of sidewalls, at least one of the pair of sidewalls having at least one lateral void.

8. The top or bottom part of claim 7, wherein the at least one void of the at least one sidewall corresponds with at least one contact area at a lower edge of a circuit board.

9. The top or bottom part of claim 7, wherein the one or more guide rails are aligned in the direction of insertion for the mounting of the circuit board.

10. The top or bottom part of claim 7, wherein both sidewalls of the guide rail each have at least one void.

11. The top or bottom part of claim 10, wherein the voids are positioned in pairs opposite each other.

12. The top or bottom part of claim 7, wherein a distance between the sidewalls of the guide rail corresponds with a thickness of the circuit board.
